(19) United States
(12) Patent Application Publication
(10) Pub. No.: US 2007/0249109 A1
(43) Pub. Date: Oct. 25, 2007

(54) Optical device and optical module

(76) Inventors: Hiroyuki Kamiyama, Saitama (JP); Takashi Toyonaka, Yokohama (JP)

Correspondence Address: MCDERMOTT WILL & EMERY LLP, 600 13TH STREET, N.W., WASHINGTON, DC, 20005-3096, US

(21) Appl. No.: 11/785,926

(22) Filed: Apr. 20, 2007

(30) Foreign Application Priority Data
Apr. 20, 2006 (JP) 2006-116473

(51) Int. Cl. H01L 33/00; H01L 21/338

(52) U.S. Cl. 438/167; 257/95

(57) ABSTRACT

A high resistance re-grown layer is disposed around an optical device having a mesa structure. Thus, a mesa portion having a plane direction that appears in etching of a circular main structure is coated with the re-grown layer. Because of this coating, it is possible to reduce the capacitance in this portion as well as to avoid the risk of disconnection with respect to all the wiring directions. The thickness of the re-grown layer can be set to be equal to the thickness of the main structural part. Particularly, when a conductive substrate is used, a substantial reduction effect of parasitic capacitance can be expected from a combination with plural dielectric films.

### CLAIM OF PRIORITY

The present application claims priority from Japanese patent application serial no. 2006-116473, filed on Apr. 20, 2006, the content of which is hereby incorporated by reference into this application.

### BACKGROUND OF THE INVENTION

The present invention relates to a semiconductor optical device, and particularly to an optical device and an optical module that are appropriate for use in optical communications.

In an optical functional device (optical device) such as a light emitting device for transmitting an optical signal in direction perpendicular to a substrate or a light receiving device for receiving an optical signal from direction perpendicular to the substrate, when the optical device has a mesa-shaped active region, it is necessary to consider avoiding disconnection of wiring in a step portion and to consider reducing parasitic capacitance caused by the wiring and electrode pad.

Thus, in JP-A No. 5600/2005, a step difference is reduced by growth of an active region with respect to a high resistance substrate in which the step is formed in advance, and then a wiring is formed on the high resistance substrate. Further, in JP-A No. 112595/1994, a wiring is formed over a high resistance semiconductor layer contacting an active region.

However, in the structure described in JP-A No. 5600/2005 or in JP-A No. 112595/1994, disconnection of wiring may not be fully avoided when a mesa structure is high and a dielectric film is thick. Further, the direction of wiring is restricted in the above described structure. Still further, the reduction of capacitance is insufficient in the above described structures.

### SUMMARY OF THE INVENTION

With respect to a surface emitting type light emitting device and a surface illuminated type light receiving device each having a mesa portion, a high resistance re-grown layer is provided around the mesa portion. In this way, the mesa portion having a plane direction that appears in etching of a circular main structure is coated with the re-grown layer. Thus, it is possible to reduce capacitance in this portion. Further the direction of wiring is not restricted. The thickness of the re-grown layer can be set to be equal to the thickness of the main structural part. Thus, particularly, when a conductive substrate is used, a substantial reduction effect of parasitic capacitance can be expected from a combination with plural dielectric films.

The above can be achieved by an optical device constituted by semiconductor layers including a semiconductor substrate on which a mesa-shaped active region is formed. Of the semiconductor layers, the semiconductor substrate or a first semiconductor layer disposed in the vicinity of the semiconductor substrate has a first conductivity. With respect to the active region of the optical device, at least a part of a wiring from a second semiconductor layer disposed on the other side of the semiconductor substrate and an electrode pad for bonding formed at one end of the wiring are formed over a high resistance semiconductor layer that is grown so as to contact the periphery of the mesa-shaped active region, via a dielectric layer.

Further, the above can be achieved by a light receiving device constituted by semiconductor layers including a semiconductor substrate on which a mesa-shaped active region is formed. The light receiving device receives light from direction perpendicular to the semiconductor substrate. Of the semiconductor layers, the semiconductor substrate or a first semiconductor layer disposed in the vicinity of the semiconductor substrate has a first conductivity. With respect to the active region of the light receiving device, at least a part of a wiring from a second semiconductor layer disposed on the other side of the semiconductor substrate and an electrode pad for bonding formed at one end of the wiring, are formed over a high resistance semiconductor layer that is grown so as to contact the periphery of the mesa-shaped active region, via a dielectric layer.

Further, the above can be achieved by a light emitting device constituted by semiconductor layers including a semiconductor substrate on which a mesa-shaped active region is formed. The light emitting device transmits light in direction perpendicular to the semiconductor substrate. Of the semiconductor layers, the semiconductor substrate or a first semiconductor layer disposed in the vicinity of the semiconductor substrate has a first conductivity. With respect to the active region of the light emitting device, at least a part of a wiring from a second semiconductor layer disposed on the other side of the semiconductor substrate and an electrode pad for bonding formed at one end of the wiring are formed over a high resistance semiconductor layer that is grown so as to contact the periphery of the mesa-shaped active region, via a dielectric layer.

Further, the above can be achieved by an optical module including at least a light receiving device and a negative feedback amplifier connected to the light receiving device to covert a current input to a voltage output. The light receiving device is constituted by semiconductor layers including a semiconductor substrate. Of the semiconductor layers, the semiconductor substrate or a first semiconductor layer disposed in the vicinity of the semiconductor substrate has a first conductivity. With respect to the active region of the light receiving device, at least a part of a wiring from a second semiconductor layer disposed on the other side of the semiconductor substrate and an electrode pad for bonding formed at one end of the wiring are formed over a high resistance semiconductor layer that is grown so as to contact the periphery of the mesa-shaped active region, via a dielectric layer.

Further, the above can be achieved by an optical module including at least a light emitting device and a driver for driving the light emitting device. The light emitting device is constituted by semiconductor layers including a semiconductor substrate. Of the semiconductor layers, the semiconductor substrate or a first semiconductor layer disposed in the vicinity of the semiconductor substrate has a first conductivity. With respect to the active region of the light emitting device, at least a part of a wiring from a second semiconductor layer disposed on the other side of the semiconductor substrate and an electrode pad for bonding formed at one end of the wiring are formed over a high resistance semiconductor layer that is grown so as to contact the periphery of the mesa-shaped active region, via a dielectric layer.

### BRIEF DESCRIPTION OF THE DRAWINGS

Preferred embodiments of the present invention will now be described in conjunction with the accompanying drawings, in which:

FIG. 1 is a cross-sectional view of a top-illuminated-type APD (Avalanche Photo Diode) device;

FIG. 2 is a block diagram of an optical receiver module in which the APD device is mounted;

FIG. 3 is a cross-sectional view of a bottom-illuminated-type APD device;

FIG. 4 is a cross-sectional view of a top-illuminated-type pin-PD device;

FIG. 5 is a block diagram of a module in which the pin-PD is mounted;

FIG. 6 is a cross-sectional view of a bottom-illuminated-type pin-PD device;

FIG. 7 is a cross-sectional view of a top-emitting-type surface emitting laser diode;

FIG. 8 is a block diagram of an optical transmitter module in which the surface emitting laser diode is mounted; and

FIG. 9 is a cross-sectional view of a bottom-emitting-type surface emitting laser diode.

### DESCRIPTION OF THE PREFERRED EMBODIMENTS

Hereinafter modes for carrying out the present invention will be described using the embodiments with reference to the drawings.

### Embodiment 1

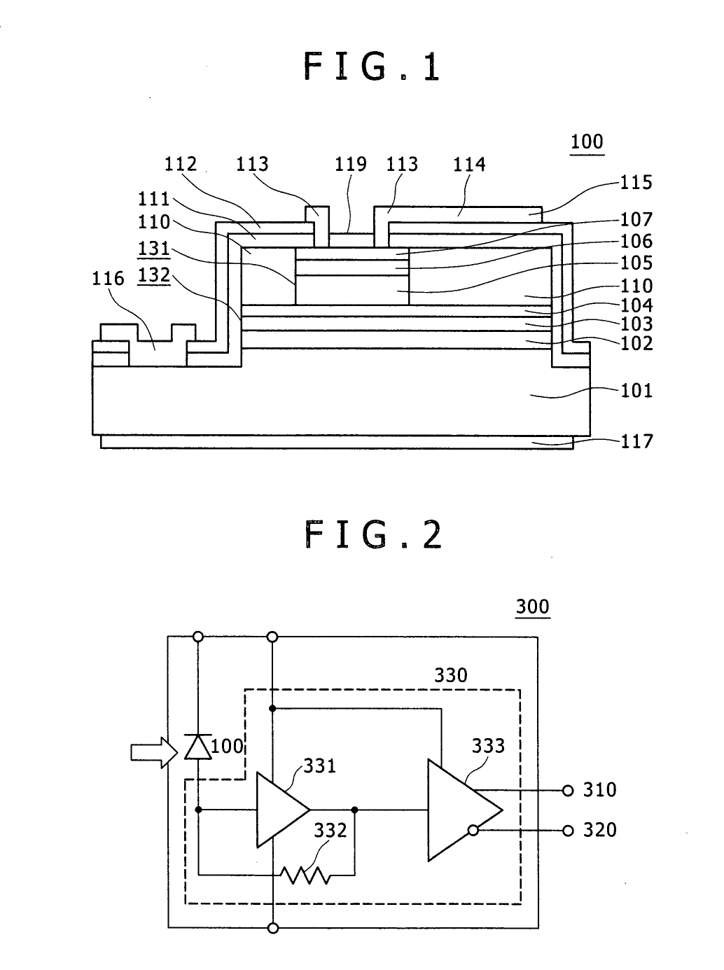

Embodiment 1 will be described with reference to FIGS. 1 and 2. Here FIG. 1 is a cross-sectional view of a top-illuminated-type APD (Avalanche Photo Diode) device. FIG. 2 is a block diagram of an optical receiver module in which the APD device is mounted. In order to avoid complexity of illustration, hatching indicating cross sections is omitted in FIG. 1 and subsequent cross-sectional views.

In FIG. 1, an APD device 100 has a structure in which a lower buffer layer 102 (conductive type: n-type InAlAs layer, impurity concentration: 1E18 cmˆ−3 (1×10¹⁸ cm⁻³), thickness: 0.5 μm (micrometers)), a multiplication layer 103 (n-type InAlAs layer, 1E14 cmˆ−3, 0.4 μm), a field-control layer 104 (p-type InAlAs layer, 8E17 cmˆ−3, 0.04 μm), an absorption layer 105 (p-type InGaAs layer, 1E15 cmˆ−3, 1.8 μm), a cap layer 106 (upper buffer layer) (p-type InAlAs layer, 1E18 cmˆ−3, 0.7 μm), and a p-type contact layer 107 (p-type InGaAs layer, 5E18 cmˆ−3, 0.1 μm) are laminated over an InP substrate 101 (n-type, 1E18 cmˆ−3) by a MOCVD (Metal Organic Chemical Vapor Deposition) method. Here, the upper and lower buffer layers 102, 106 are functional parts to confine electrons. The absorption layer 105 is a photo-sensitive layer. The multiplication layer 103 is literally a multiplication layer. Further the field-control layer 104 between the absorption layer 105 and the multiplication layer 103 controls the field balance between them.

A main active region of the APD 100 has a two-step mesa structure. A first mesa 131 is formed inside the main active region by etching halfway from the p-type contact layer 107 to the field-control layer 104, using phosphoric acid solution. A second mesa 132 is formed by filling the periphery of the first mesa 131 with an InP re-grown layer 110 (high resistance, 2.0 μm), and by etching the outside thereof from the InP re-grown layer 110 to the InP substrate 101, using an HBr-based etching solution. Although the total film thickness of the absorption layer 105, the cap layer 106, and the p-type contact layer 107 is 2.6 μm, the InP re-grown layer 110 is thin with a thickness of 2.0 μm. This is because that the InP re-grown layer 110 is thickly formed around the protruding first mesa 131. Incidentally when the high resistance InP re-grown layer 110 is undoped, it may be intentionally doped to have a high resistance. The impurity concentration of the undoped layer is 1E15 cmˆ−3 or less.

Here SiN film 111 (0.2 μm) and SiO₂ film 112 (0.4 μm) were used as dielectric protective films over the semiconductor layer. The dielectric films are provided with a contact hole. A p-type ohmic electrode 113 (Ti/Pt/Au, 0.7 μm) is brought into contact with the p-type contact layer 107 through the contact hole. A wiring portion 114 (width: 10 μm, length: 40 μm) and electrode pad 115 (75 μmφ (phi)) of the p-type ohmic electrode 113 are disposed over the SiN film 111, SiO₂ film 112, and InP re-grown film 110. With this structure, the parasitic capacitance is reduced thereby preventing disconnection of the wiring. Incidentally, an n-type ohmic electrode 116 is formed simultaneously with the formation of the p-type ohmic electrode 113. The bottom side of the InP substrate in which no device active region is provided is ground to a thickness of 200 μm, and then a bottom metal film 117 (AuGe/Ni/Ti/Pt/Au, thickness: 0.8 μm) for die bonding is formed. An anti-reflection coating 119 in a light receiving portion is the SiN film that is formed simultaneously with the formation of the dielectric films as described above.

The characteristics of the device with a light receiving diameter of 40 μmφ were evaluated by applying reverse bias voltage. The result was good with a breakdown voltage of 40 V and a dark current of 15 nA at 36 V. The parasitic capacitance was fully reduced with a 0.3 pF intermediate value of the capacitance distribution across the entire wafer. In addition, the result of the open defect including disconnection of the wiring was good with a rate less than 1%.

In the above Embodiment 1, the description was made taking the two-step mesa structure as an example of the structure of the APD. However, it is possible to take another mesa structure with different order and combination of etching and crystal regrowth. There were used InAlAs as the multiplication layer material and InGaAs as the absorption material, but the effect is the same when other material systems are used. Further although the n-type InP substrate was used, it is possible that an n-type contact layer is provided in the vicinity of the InP substrate and an n-type ohmic electrode is connected to the contact layer.

With the same APD structure as described above, the evaluation was made using only the dielectric films without using the InP re-grown layer under the wiring and electrode pad of the p-type electrode (Comparative Example 1 not shown) by applying reverse bias voltage. As a result, the rate of the open defect including disconnection of the wiring was very high with 80%. In the case of the device that was successfully measured without any disconnection, the intermediate value of the capacitance distribution across the entire wafer was also high with a value of 1.0 pF.

The inventors consider that the differences of the defect rates and capacitances between Embodiment 1 and Comparative Example 1 are caused by the total film thickness of the dielectric layer, the step difference between the top portion and the bottom portion in the mesa active region, and the thickness of the re-grown semiconductor layer. The boundary values appear as significant differences when the total thickness of the dielectric films exceeds 0.4 μm, or when the step difference between the top portion and the bottom portion in the mesa active region excluding the re-grown semiconductor layer exceeds 2 μm, or when the thickness of the re-grown semiconductor layer exceeds 0.6 μm.

According to the embodiment, the mesa portion having a plane direction that appears in etching of the circular main structure is also coated with the re-grown layer, so that the parasitic capacitance can be reduced in this portion. It is also possible to avoid risk of disconnection with respect to all the wiring directions.

An optical receiver module 300 shown in FIG. 2 includes the APD device 100 and a TIA (Trans Impedance Amplifier) with limiting amplifier 330. The TIA with limiting amplifier 330 includes a preamplifier 331, a feedback resister 332, and a limiting amplifier 333, to serve as a negative feedback amplifier for converting the current input to the voltage output. The optical receiver module 300 receives an optical signal indicated by the arrow. The optical signal is output as an electrical signal from an OUT1 terminal 310 which is a positive phase output of the TIA with limiting amplifier 330, and from an OUT2 terminal 320 which is a reverse phase output thereof.

The optical receiver module 300 has a small capacitance while the APD device 100 has a relatively large light receiving diameter of 40 μmφ. Thus, the optical receiver module 300 can be combined with a preamplifier of low input impedance, thereby achieving excellent high frequency response characteristics. Further, the optical receiver module 300 is easy for optical axis alignment, low in cost and high in yield for a high-speed application at 2.5 Gbits/s or more.

### Embodiment 2

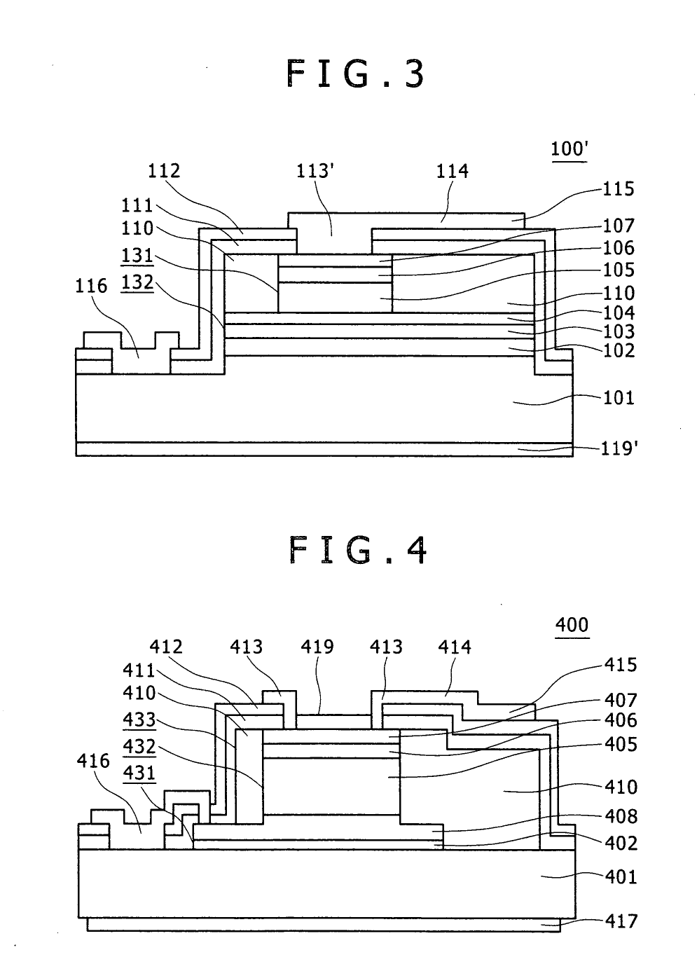

In Embodiment 1, the top-illuminated-type APD device has been described. In Embodiment 2, a bottom-illuminated-type APD device will be described with reference to FIG. 3. Here FIG. 3 is a cross-sectional view of a bottom-illuminated-type APD device. Incidentally, as the structure of Embodiment 2 is generally the same as that of Embodiment 1, substantially like parts are denoted by like reference numerals and the description will not be repeated.

In a bottom-illuminated-type APD device 100′ shown in FIG. 3, the anti-reflection coating 119 (SiN film), which is provided in the light receiving portion of the top-illuminated-type APD device in FIG. 1, is eliminated by etching and a p-type ohmic electrode 113′ is formed over the entire portion. As it is the bottom illuminated type, an anti-reflection coating 119′ is provided in place of the bottom metal film 117 for die bonding.

With the bottom-illuminated-type APD device according to the embodiment, the same effect as the APD device of Embodiment 1 can be obtained. Further, with the optical receiver module using the bottom-illuminated-type APD device of Embodiment 2, the same effect as the optical receiver module of Embodiment 1 can also be obtained.

### Embodiment 3

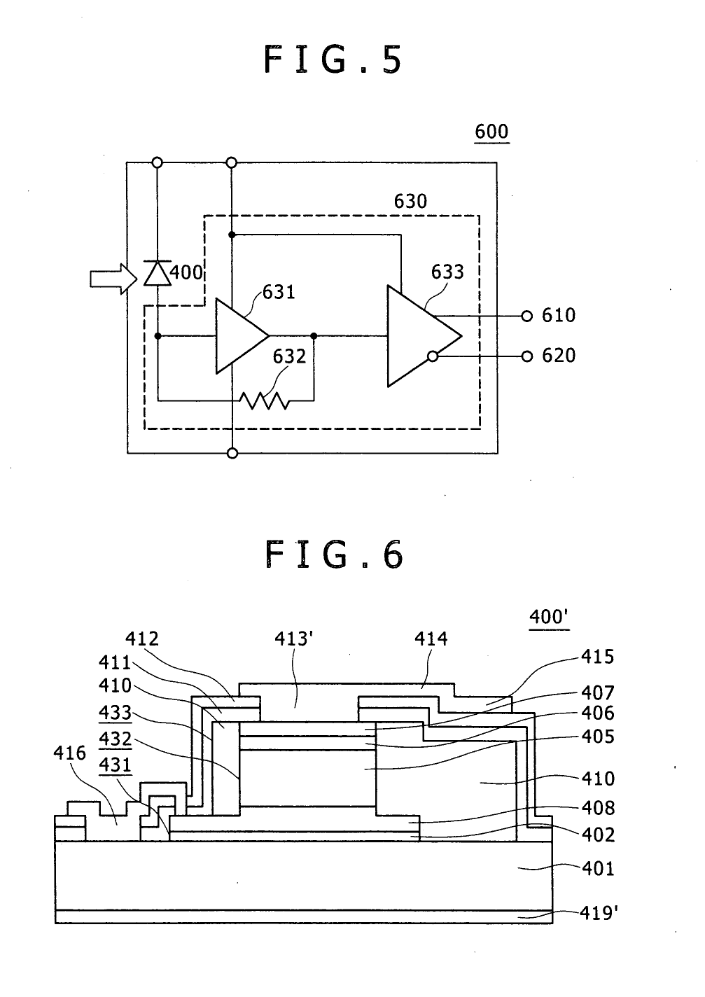

Embodiment 3 will be described below with reference to FIGS. 4 and 5. Here FIG. 4 is a cross-sectional view of a top-illuminated-type pin-PD device. FIG. 5 is a block diagram of an optical receiver module in which the pin-PD device is mounted.

In FIG. 4, a pin-PD device 400 has a structure in which a buffer layer 402 (undoped InP layer, 0.2 μm), an n-type contact layer 408 (n-type InGaAsP layer, 8E18 cmˆ−3, 0.4 μm), an absorption layer 405 (n-type InGaAs layer, 5E14 cmˆ−3, 2.0 μm), a cap layer 406 (p-type InGaAsP layer, 1E18 cmˆ−3, 0.2 μm), and a p-type contact layer 407 (p-type InGaAs layer, 1E19 cmˆ−3, 0.1 μm) are laminated over an InP (semi-insulating) substrate 401. The main active region of the pin-PD structure in the PD device 400 is formed by a three-step mesa technology. An outermost first mesa 431 is a step between the n-type contact layer 408 and the InP substrate 401. The first mesa 431 is formed by a combination of a vertical portion etched from the p-type contact layer 407 to the InP substrate 401 with phosphoric acid solution, and a horizontal portion formed by etching of a third mesa 433.

An innermost second mesa 432 is formed by etching from the p-type contact layer 407 to the n-type contact layer 408 with phosphoric acid solution. The third mesa 433 is formed by filing the periphery of the second mesa 432 with an InP re-grown layer 410 (high resistance, 2 μm), and by further etching the outside thereof with phosphoric acid etching solution from the InP re-grown layer 410 to the n-type contact layer 408.

Here, there were used SiN film 411 (0.16 μm) and SiO₂ film 412 (0.5 μm) as dielectric films (protective films) over the semiconductor layer. A p-type ohmic electrode 413 (Ti/Pt/Au, 0.7 μm) is brought into contact with the contact layer 406. Then a wiring portion 414 (width: 5 μm, length: 100 μm) and an electrode pad 415 (90 μmφ) of the p-type ohmic electrode 413 are disposed over the SiN film 411, SiO₂ film 412, and InP re-grown layer 410. With this structure, the parasitic capacitance is reduced thereby preventing disconnection of the wiring. Further, an n-type ohmic electrode 416 (AuGe/Ni/Ti/Pt/Au, thickness: 0.8 μm) is brought into contact with the n-type contact layer 408. The wiring 414 and the electrode pad 415 are formed on the top side in such a way that the wiring 414 is provided over the dielectric films and the semi-insulating InP substrate 401, and that the electrode 415 pad is provided over the dielectric films and the InP re-grown layer 410. The bottom side of the InP substrate 401 in which no device active region is disposed is ground to a thickness of 300 μm. Then a bottom metal film 417 (AuGe/Ni/Ti/Pt/Au, thickness: 0.8 μm) for die bonding was disposed. An anti-reflection coating 419 is the SiN film (0.16 μm) which was formed as a portion of the dielectric layer.

The characteristics of the device with a light receiving diameter of 30 μmφ were evaluated by applying reverse bias voltage. The result of the dark current was good with a value of 1 nA at 1.5 V. The parasitic capacitance was fully reduced with a 0.15 pF intermediate value of the capacitance distribution across the entire wafer. In addition, the result of the open defect including disconnection of the wiring was good with a rate of less than 1%.

In the above described example, the three-step mesa structure was taken as the structure of the pin-PD. However, it is possible to take another mesa structure with different order and combination of etching and crystal regrowth. Further although InGaAs was used as the absorption material, the effect is the same when other material systems are used.

With the pin-PD structure of Embodiment 3, the evaluation was made using only the dielectric films without using the InP re-grown layer under the wiring and electrode pad of the p-type electrode (Comparative Example 2 not shown). As a result, the rate of the open defect including the disconnection of the wiring was high with 20%. In the case of the device that was successfully measured without any disconnection, the parasitic capacitance was not reduced with a 0.3 pF intermediate value of the capacitance distribution across the entire wafer. The results show that the defect rate is high due to band failure when the device is used for the module for a high-speed application at 10 Gbits/s or more.

The inventors consider that the differences of the defect rates and capacitances between Embodiment 3 and Comparative Example 2 are caused by the total film thickness of the dielectric layer, the step difference between the top portion and the bottom portion in the mesa active region, and the thickness of the re-grown semiconductor layer. The boundary values appear as significant differences when the total thickness of the dielectric films exceeds 0.4 μm, or when the step difference between the top portion and the bottom portion in the mesa active region excluding the re-grown semiconductor layer exceeds 2 μm, or when the thickness of the re-grown semiconductor layer exceeds 0.6 μm.

According to the embodiment, the mesa portion having a plane direction that appears in etching of the circular main structure is also coated with the re-grown layer, so that the parasitic capacitance can be reduced in this portion. It is also possible to avoid risk of disconnection with respect to all the wiring directions.

An optical receiver module 600 shown in FIG. 5 includes the pin-PD 400 and a TIA with limiting amplifier 630. The TIA with limiting amplifier 630 includes a preamplifier 631, a feedback resistance 632, and a limiting amplifier 633. The optical receiver module 600 receives an optical signal indicated by the arrow. The optical signal is output as an electrical signal from an OUT1 terminal 633 which is a positive phase output of the TIA with limiting amplifier 630, and from an OUT2 terminal 634 which is a reverse phase output thereof.

The optical receiver module 600 has a small capacitance while the pin-PD 400 has a relatively large light receiving diameter of 30 μmφ. Thus, the optical receiver module 600 can be combined with a preamplifier of low input impedance, thereby achieving excellent high frequency response characteristics. Further, the optical receiver module 600 is easy for optical axis alignment, low in cost and high in yield for a high-speed application at 10 Gbits/s or more.

### Embodiment 4

In Embodiment 3, the top-illuminated-type pin-PD device has been described. In Embodiment 4, a bottom-illuminated-type pin-PD device will be described with reference to FIG. 6. Here, FIG. 6 is a cross-sectional view of a bottom-illuminated-type pin-PD device. Incidentally, as the structure of Embodiment 4 is generally the same as that of Embodiment 3, substantially like parts are denoted by like reference numerals and the description will not be repeated.

In FIG. 6, the anti-reflection coating 419 (SiN film, thickness: 0.2 μm), which is provided in the light receiving portion of the top-illuminated-type pin-PD device of FIG. 4, is eliminated by etching. Then a p-type ohmic electrode 413′ is formed over the entire portion. As it is the bottom illuminated type, an anti-reflection coating 419′ (thickness: 0.2 μm) is provided in place of the bottom metal film 417 for die bonding.

With the bottom-illuminated-type pin-PD device according to the embodiment, the same effect as the pin-PD device of Embodiment 3 can be obtained. Further, with the optical receiver module using the pin-PD device of the present embodiment, the same effect as the optical receiver module of Embodiment 3 can also be obtained.

### Embodiment 5

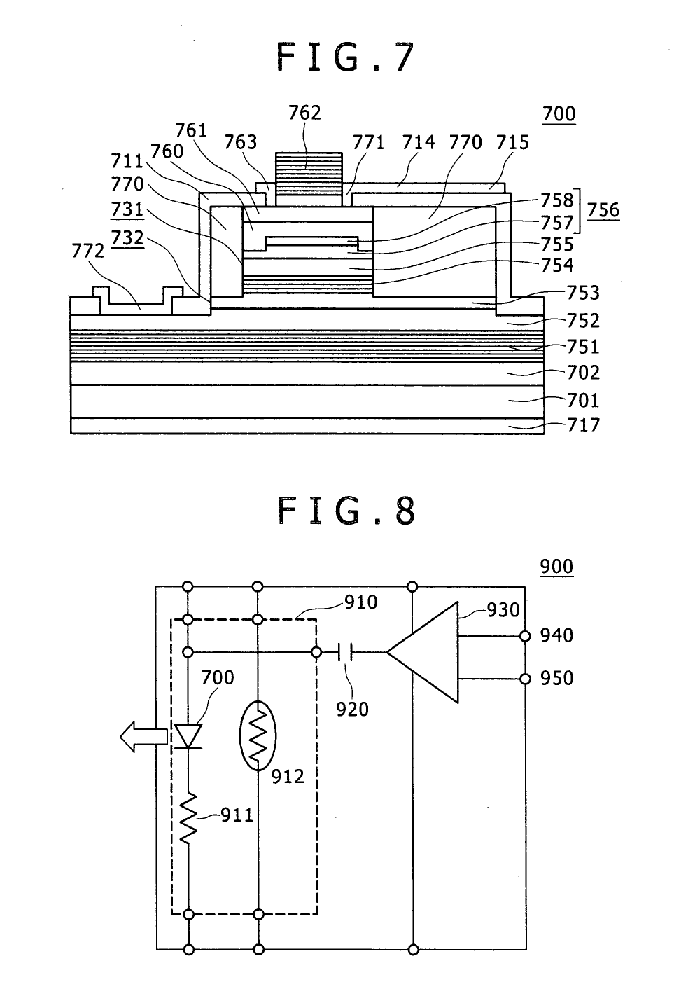

Embodiment 5 will be described below with reference to FIGS. 7 and 8. Here, FIG. 7 is a cross-sectional view of a top-emitting-type surface emitting laser diode. FIG. 8 is a block diagram of an optical transmitter module in which the surface emitting laser diode is mounted.

In FIG. 7, a top-emitting-type surface emitting laser diode 700 has a structure in which a buffer layer 702 (n-type InP layer, 1E18 cmˆ−3, 0.2 μm), semiconductor reflection mirror 751 (n-type, InAlAs/InGaAlAs layer, 1E18 cmˆ−3, 42-cycle structure of λ/4 film thickness each), lower contact layer 752 (n-type InP layer, 5E17 cmˆ−3, 0.2 μm), cladding layer 753 (n-type InAlAs layer, 5E17 cmˆ−3, 0.2 μm); MQW layer 754 (InGaAlAs well/barrier: 7 cycles, thickness: 0.2 μm), cladding layer 755 (p-type InAlAs layer, 5E17 cmˆ−3, 0.7 μm), tunnel junction layer 756 (p+InGaAlAs/n+InGaAs layer, 1E19 cmˆ−3, 20 nm/12 nm, where “/” represents “lower layer/upper layer”) are laminated over an InP substrate 701 (n-type, 1E18 cmˆ−3) by the MOCVD method.

A current confinement area is formed by the following procedure. With respect to a portion other than a current confinement area of the tunnel junction layer 756, all of the upper n+InGaAs layer 758 and a portion of the lower p+InGaAlAs layer 757 are eliminated by dry etching, on which an n−InP re-grown layer 760 (n-type, thickness: 0.1 μm) and an upper contact layer 761 (n-type InGaAs layer, 2E19 cmˆ−3, 0.1 μm) are grown. In order to avoid formation of tunnel junction outside the current confinement area, the impurity concentration of the n-InP layer 760 is reduced to 5E17 cmˆ−3 from the start of growth to when the thickness is 10 nm, and subsequently the impurity concentration is set to 5E18 cmˆ−3 until when the thickness is 0.1 μm. Further, in order to avoid absorption loss, the upper contact layer 761 (InGaAs layer) is selectively etched by wet etching to eliminate portions directly on and around the current confinement area, on which a dielectric multilayer film mirror 762 (Al₂O₃/a-Si, 4-cycle structure of λ/4 film thickness each) is formed.

The outside of a ring-shaped electrode opening 763 is provided with a two-step mesa structure to reduce leakage current and capacitance. A first mesa 731 is formed by etching from the InGaAs upper contact layer 761 to the cladding layer 753 with phosphoric acid etching solution. A second mesa 732 is formed by filling the periphery of the first mesa 731 with a high resistance InP re-grown layer 770 (thickness: 0.6 μm), and by further etching the outside thereof from the high resistance InP re-grown layer 770 to the InP lower contact layer 752.

Here, SiN film 711 (0.25 μm) is formed as a protective film over the semiconductor layer excluding an area in which the dielectric multilayer film mirror 762 is formed and an area in which the electrode contacts the semiconductor. An upper ohmic electrode 771 (AuGe/Ni/TiPt/Au, thickness: 0.7 μm) is brought into contact with the semiconductor by the upper contact layer 761 and the ring electrode 763. A wiring portion 714 (width: 5 μm, length: 100 μm) and an electrode pad 715 (75 μmφ) are disposed over the SiN film 711 and the InP re-grown layer 770. With this structure, the parasitic capacitance is reduced thereby preventing disconnection of the wiring.

Further, a lower ohmic electrode 772 (AuGe/Ni/Ti/Pt/Au, thickness: 0.7 μm) is also formed on the top side simultaneously with the formation of the upper ohmic electrode 771. The bottom side of the InP substrate 701 in which no device active region is disposed, is ground to a thickness of 100 μm. Then a bottom metal film 717 (AuGe/Ni/Ti/Pt/Au, thickness: 0.8 μm) for die bonding is formed.

The top-emitting-type surface emitting laser diode 700 of FIG. 7 injects current into a narrow region of the MQW layer 754 to emit a light by means of the tunnel junction layer 756. The light is resonated between the lower semiconductor reflection mirror 751 and the upper dielectric multilayer film mirror 762. Then a laser beam with an emission wavelength of 1.55 μm is output from the dielectric multilayer film mirror 762.

With respect to the above described top-emitting-type surface emitting laser diode 700, the evaluation was made using the surface emission laser diode with an output window of 15 μm. The result was good with an emission wavelength of 1.55 μm, a threshold of 2 mA, and a slope efficiency of 50%. The parasitic capacitance was fully reduced with a 0.23 pF intermediate value of the capacitance distribution across the entire wafer. In addition, the result of the open defect including disconnection of the wiring was good with a rate of less than 1%.

In the above described example, the two-step mesa structure was taken as the structure of the top-emitting-type surface emitting laser diode. However, it is also possible to take another mesa structure with different order and combination of etching and crystal regrowth. For example, the first mesa may be formed to an interface between the n+InGaAs layer 758 and the p+InGaAlAs layer 757, the halfway of the tunnel junction layer 756. Further, although the InGaAs MQW structure was used as the active region material, the effect is the same when other material systems are used.

With respect to the top-emitting-type surface emitting laser diode, the evaluation was made using only the dielectric film without using the InP re-grown layer under the electrode wiring and the electrode pad (Comparative Example 3 not shown) As a result, the rate of the open defect including disconnection of the wiring was high with 30%. In the case of the device that was successfully measured without any disconnection, the parasitic capacitance was large with a 1.1 pF intermediate value of the capacitance distribution across the entire wafer. The results show that the defect rate is high due to band failure when the device is used for the module for a high-speed application at 2.5 Gbits/s or more.

The inventors consider that the differences of the defect rates and the capacitances between Embodiment 5 and Comparative Example 3 are caused by the total film thickness of the dielectric layer, the step difference between the top portion and the bottom portion in the mesa active region, and the thickness of the re-grown semiconductor layer. The boundary values appear as significant differences when the total thickness of the dielectric film exceeds 0.4 μm, or when the step difference between the top portion and the bottom portion in the mesa active region excluding the re-grown semiconductor layer exceeds 2 μm, or when the thickness of the re-grown semiconductor layer exceeds 0.6 μm.

According to the embodiment, the mesa portion having a plane direction that appears in etching of the circular main structure is also coated with the re-grown layer, so that the parasitic capacitance can be reduced in this portion. It is also possible to avoid risk of disconnection with respect to all the wiring directions.

An optical transmitter module 900 shown in FIG. 8 includes a laser module 910, and a driver circuit 930 for supplying a drive current to the laser module 910 via a capacitance device 920 for capacitance coupling. The driver circuit 930 is supplied with a positive electrical signal from an IN1 terminal 940 and a reverse electrical signal from an IN2 terminal 950, respectively. The laser module 910 includes the surface emitting laser diode 700, a thermistor for temperature monitoring of the surface emitting laser diode 700, and a resistance device 911 connected to a cathode side of the surface emitting laser diode 700. Here the resistance device 911 is designed for 50 ohm matching. The drive current from the driver circuit 930 is supplied to an anode of the surface emitting laser device 700. The surface emitting laser diode 700 according to the embodiment has a small capacitance while the output window has a relatively large diameter of 15 μmφ. This makes it possible to manufacture an optical module which is excellent in high frequency response characteristics, easy for optical axis alignment, and low in cost and high in yield for a high-speed application at 2.5 Gbits/s or more.

### Embodiment 6

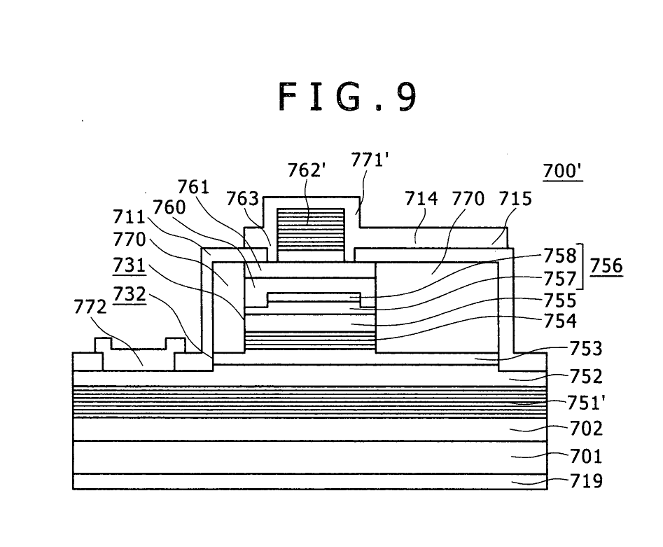

In Embodiment 5, the top-emitting-type surface emitting laser diode has been described. In Embodiment 6, a bottom-emitting-type surface emitting laser diode will be described with reference to FIG. 9. Here, FIG. 9 is a cross-sectional view of a bottom-emitting-type surface emitting laser diode. Incidentally, as the structure of Embodiment 6 is generally the same as that of Embodiment 5, substantially like parts are denoted by like reference numerals and the description will not be repeated.

In the figure, a semiconductor reflection mirror 751′ on the lower side includes an n-type InAlAs/InGaAlAs layer, 1E18 cmˆ−3, 31-cycle structure of λ/4 film thickness each. A dielectric multilayer film mirror 762′ on the upper side includes Al₂O₃/a-Si, 8-cycle structure of λ/4 film thickness each. As a result, a laser beam with a resonant wavelength of 1.55 μm is output from the semiconductor multilayer film mirror 751′. Incidentally the InP substrate 701 and the buffer layer 702 are transparent to the resonant wavelength.

Here an upper ohmic electrode 771 is designed to cover the dielectric multilayer film mirror 762′. The bottom of the InP substrate 701 is provided with the SiN film 719 (0.16 μm) for anti-reflection coating. The SiN film 719 is provided so that another resonator is not formed inside the bottom-emitting-type surface emitting laser diode due to reflection at an interface between air and the InP where reflection is relatively large.

With the bottom-emitting-type surface emitting laser diode according to the embodiment, it is possible to obtain the same effect as the top-emitting-type surface emitting laser diode of Embodiment 5. Further, with the optical transmitter module using the pin-PD device of the present embodiment, the same effect as the optical transmitter module of Embodiment 5 can also be obtained.

Incidentally, in the present specification, the optical device includes the light emitting device and the light receiving device, but is not limited thereto. Similarly the optical module includes the optical transmitter module and the optical receiver module, but is not limited thereto.

According to the present invention, the mesa portion having a plane direction that appears in etching of the circular main structure is also coated with the re-grown layer, so that the parasitic capacitance can be reduced in this portion. It is also possible to avoid risk of disconnection with respect to all the wiring directions.

We claim:

1. An optical device in which a mesa-shaped active region is formed over a semiconductor substrate, comprising:
semiconductor layers including said semiconductor substrate,
of said semiconductor layers, said semiconductor substrate or a first semiconductor layer disposed in the vicinity of said semiconductor substrate having a first conductivity, and
with respect to the active region of said optical device, at least a part of a wiring from a second semiconductor layer disposed on the other side of said semiconductor substrate and an electrode pad for bonding formed in one end of said wiring being formed over a high resistance semiconductor layer that is grown so as to contact the periphery of said mesa-shaped active region, via a dielectric layer.

2. The optical device according to claim 1, wherein the thickness of said dielectric film of said optical device is 0.4 μm or more.

3. The optical device according to claim 1, wherein a step difference between a top portion and a bottom portion in said mesa-shaped active region of said optical device is 2 μm or more.

4. The optical device according to claim 1, wherein the thickness of said high resistance semiconductor layer of said optical device is 0.6 μm or more.

5. The optical device according to claim 1, wherein said semiconductor substrate has said first conductivity.

6. The optical device according to claim 2, wherein said semiconductor substrate has said first conductivity.

7. The optical device according to claim 3, wherein said semiconductor substrate has said first conductivity.

8. The optical device according to claim 4, wherein said semiconductor substrate has said first conductivity.

9. The optical device according to claim 1,
wherein said semiconductor substrate has semi-insulating properties, and
said first semiconductor layer disposed in the vicinity of said semiconductor substrate has said first conductivity.

10. The optical device according to claim 2,
wherein said semiconductor substrate has semi-insulating properties, and
said first semiconductor layer disposed in the vicinity of said semiconductor substrate has said first conductivity.

11. The optical device according to claim 3,
wherein said semiconductor substrate has semi-insulating properties, and
said first semiconductor layer disposed in the vicinity of said semiconductor substrate has said first conductivity.

12. The optical device according to claim 4,
wherein said semiconductor substrate has semi-insulating properties, and
said first semiconductor layer disposed in the vicinity of said semiconductor substrate has said first conductivity.

13. The optical device according to claim 1, wherein said optical device is a light receiving device or a light emitting device.

14. The optical device according to claim 2, wherein said optical device is a light receiving device or a light emitting device.

15. The optical device according to claim 3, wherein said optical device is a light receiving device or a light emitting device.

16. The optical device according to claim 4, wherein said optical device is a light receiving device or a light emitting device.

17. An optical module comprising:
at least a light receiving device; and
a negative feedback amplifier connected to the light receiving device to convert a current input to a voltage output,
said light receiving device being constituted by semiconductor layers including a semiconductor substrate,
of said semiconductor layers, said semiconductor substrate or a first semiconductor layer disposed in the vicinity of said semiconductor substrate having a first conductivity, and
with respect to the active region of said light receiving device, at least a part of a wiring from a second semiconductor layer disposed on the other side of said semiconductor substrate and an electrode pad for bonding formed in one end of said wiring being formed over a high resistance semiconductor layer that is grown so as to contact the periphery of said mesa-shaped active region, via a dielectric layer.

18. An optical module comprising:
at least a light emitting device; and
a driver for driving the light emitting device,
said light emitting device being constituted by semiconductor layers including a semiconductor substrate,
of said semiconductor layers, said semiconductor substrate or a first semiconductor layer disposed in the vicinity of said semiconductor substrate having a first conductivity, and
with respect to an active region of said light emitting device, at least a part of a wiring from a second semiconductor layer disposed on the other side of said semiconductor substrate and an electrode pad for bonding formed in one end of said wiring being formed over a high resistance semiconductor layer that is grown so as to contact the periphery of said mesa-shaped active region, via a dielectric layer.
